(19) United States
(12) Patent Application Publication
(10) Pub. No.: US 2024/0203792 A1
(43) Pub. Date: Jun. 20, 2024

(54) SELF-ALIGNED BACKSIDE GATE CONTACTS

(71) Applicant: INTERNATIONAL BUSINESS MACHINES CORPORATION, Armonk, NY (US)

(72) Inventors: Tsung-Sheng Kang, Ballston Lake, NY (US); Tao Li, Slingerlands, NY (US); Ruilong Xie, Niskayuna, NY (US); Leon Sigal, Monsey, NY (US)

(21) Appl. No.: 18/065,965

(22) Filed: Dec. 14, 2022

(51) Int. Cl. H01L 21/768; H01L 21/311; H01L 21/8238; H01L 23/522; H01L 23/528; H01L 27/092; H01L 29/40; H01L 29/423; H01L 29/66

(52) U.S. Cl. CPC H01L 21/76897; H01L 21/31111; H01L 21/76802; H01L 21/76831; H01L 21/823871; H01L 23/5226; H01L 23/5286; H01L 27/092; H01L 29/401; H01L 29/42392; H01L 29/66545; H01L 29/0673

(57) ABSTRACT

Semiconductor devices and methods of forming the same include a channel over a backside layer. A dielectric fill is on the backside layer, including a first dielectric material. A gate conductor is on the channel and makes electrical contact with the backside layer through the dielectric fill. A dielectric liner is on sidewalls of the dielectric fill, including a second dielectric material, in contact with the gate conductor at the dielectric fill.

### BACKGROUND

The present invention generally relates to semiconductor device fabrication and, more particularly, to devices with backside signal lines.

In addition to the use of back-end-of-line (BEOL) layers to provide power and signal communication to front-end-of-line (FEOL) devices, signal and power structures may be formed on the backside of the FEOL devices. Forming vias between the frontside structures and backside structures of the semiconductor device can be challenging, as such vias pose a risk of shorting to other structures of the device.

### SUMMARY

A semiconductor device includes a channel over a backside layer. A dielectric fill is on the backside layer, including a first dielectric material. A gate conductor is on the channel and makes electrical contact with the backside layer through the dielectric fill. A dielectric liner is on sidewalls of the dielectric fill, including a second dielectric material, in contact with the gate conductor at the dielectric fill.

A semiconductor device includes a first channel over a backside layer in a first device region. A second channel is over the backside layer in a second device region. A dielectric fill includes a first dielectric layer on the backside layer between the first device region and the second device region. A gate conductor is on the first channel and the second channel and makes electrical contact with the backside layer through the dielectric fill. A dielectric liner is on sidewalls of the dielectric fill, including a second dielectric material, and is in contact with the gate conductor at the dielectric fill.

A method for forming a semiconductor device includes etching a set of vertically stacked semiconductor layers and an underlying substrate to form a trench. A multilayer dielectric structure is formed at a bottom of the trench, including a liner on sidewalls of the trench from a first dielectric material and a fill from a second dielectric material. The set of vertically stacked semiconductor layers is processed to form a channel layer. A hole is etched through the fill to expose a portion of the underlying substrate. A gate conductor is deposited that makes electrical contact with the channel layer and that fills the hole.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a step in the fabrication of a semiconductor device with self-aligned backside gate contacts, in accordance with an embodiment of the present invention;

FIG. 2 is a cross-sectional view of a step in the fabrication of a semiconductor device with self-aligned backside gate contacts, showing the formation of a stack of semiconductor layers on a substrate, in accordance with an embodiment of the present invention;

FIG. 3 is a cross-sectional view of a step in the fabrication of a semiconductor device with self-aligned backside gate contacts, showing the formation of trenches in the stack of semiconductor layers, in accordance with an embodiment of the present invention;

FIG. 4 is a cross-sectional view of a step in the fabrication of a semiconductor device with self-aligned backside gate contacts, showing the formation of a dielectric liner on sidewalls of the trenches, in accordance with an embodiment of the present invention;

FIG. 5 is a cross-sectional view of a step in the fabrication of a semiconductor device with self-aligned backside gate contacts, showing the formation of a two-layer shallow trench isolation (STI) structure, in accordance with an embodiment of the present invention;

FIG. 6 is a set of cross-sectional views of a step in the fabrication of a semiconductor device with self-aligned backside gate contacts, showing the formation of devices from the stacks of semiconductor layers, including placeholder structures under certain source/drain structures, in accordance with an embodiment of the present invention;

FIG. 7 is a set of cross-sectional views of a step in the fabrication of a semiconductor device with self-aligned backside gate contacts, showing the removal of a dummy gate to expose channel layers, in accordance with an embodiment of the present invention;

FIG. 8 is a set of cross-sectional views of a step in the fabrication of a semiconductor device with self-aligned backside gate contacts, showing the formation of an organic planarizing layer around the channel layers, including a hole that penetrates through the two-layer STI structure to expose the underlying substrate, in accordance with an embodiment of the present invention;

FIG. 9 is a set of cross-sectional views of a step in the fabrication of a semiconductor device with self-aligned backside gate contacts, showing the formation of a gate stack around the channels that reaches through the hole to the underlying substrate, in accordance with an embodiment of the present invention;

FIG. 10 is a set of cross-sectional views of a step in the fabrication of a semiconductor device with self-aligned backside gate contacts, showing the removal of substrate layers to expose a backside of the device, in accordance with an embodiment of the present invention;

FIG. 11 is a set of cross-sectional views of a step in the fabrication of a semiconductor device with self-aligned backside gate contacts, showing the formation of a backside layer, in accordance with an embodiment of the present invention; and

FIG. 12 is a block/flow diagram of a method of fabricating a semiconductor device with self-aligned backside gate contacts, in accordance with an embodiment of the present invention.

### DETAILED DESCRIPTION

Semiconductor devices, such as nanosheet field effect transistors (FETs) may include contacts that penetrate through a substrate layer to a backside of device, where there may be signal or power structures. For example, a signal line or clock line at the backside of a device may be used to trigger the device's gate. A via may therefore reach from the gate conductor on the frontside of the device, down through the substrate, to make electrical contact with backside structures.

However, with ever-decreasing device pitches and dimensions, the risk of creating an electrical short to other device structures increases. For example, when there is a wafer backside clock signal located at the boundary between an n-type device and a p-type device, near a backside power rail, there is a risk of direct shorting between a backside source/drain contact and the gate backside via to the clock signal line.

To prevent such shorting, a self-aligned gate contact may be formed to the clock signal line. Lined shallow-trench isolation (STI) regions may be formed to separate adjacent devices. These lined STI regions may have a first dielectric that is formed on sidewalls of the devices and a second dielectric that fills the trench. To form the gate contact via, a portion of the second dielectric may be selectively removed to expose the underlying substrate, without damaging the first dielectric liner. This region may be filled with conductive material to form the gate contact—the first dielectric liner prevents shorting between the gate contact and other structures, including source/drain structures and contacts.

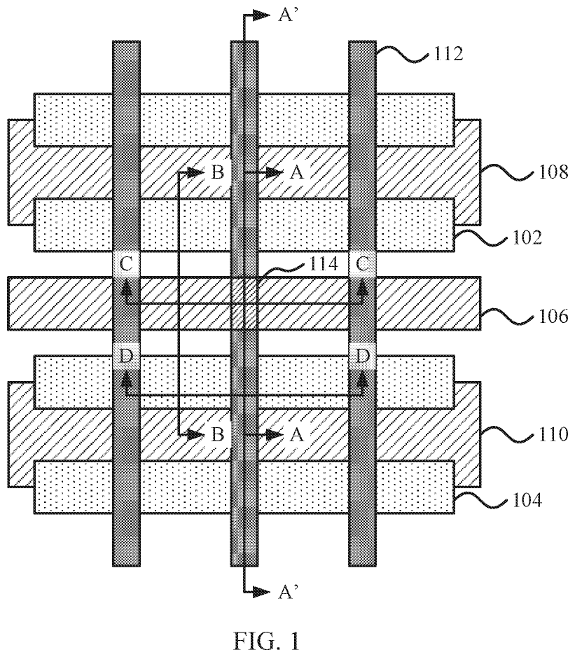

Referring now to FIG. 1, a top-down view of a step in the fabrication of a semiconductor device is shown. Two sets of FETs are shown, including a first polarity 102 and a second polarity 104. For example, the first polarity 102 may include n-type FETs (NFETs) and the second polarity 104 may include p-type FETs (PFETs). It should be understood that the positions of these polarities may be reversed, and furthermore that the two sets of FETs may be formed with the same polarity (e.g., both as NFETs or both as PFETs).

Underneath the FETs is a set of conductive lines, including a clock/signal line 106, and power lines 108 and 110, which may represent Vₛₛ and V_{dd} lines. It is specifically contemplated that the Vₛₛ line may run underneath the NFETs 102 and that the V_{dd} line may run underneath the PFETs 104, but it should be understood that any appropriate combination of polarities may be used instead. Source/drain structures of the FETs may connect to the underlying power lines by a via or any other appropriate electrical connection.

The FETs 102/104 are shown as horizontally oriented strips of semiconductor material. As will be shown in greater detail below, these devices may be formed as nanosheet FETs, but other types of device structure are also contemplated, including nanowire and fin FET structures. A set of gates 112 crosses over these strips, defining channel regions on each of the strips. Source/drain structures are defined on portions of the strips that are laterally adjacent to the gates 112. The gates 112 may cross over the two distinct sets of FETs, passing over the signal/clock line 106. A via 114 may connect a gate 112 to the signal/clock 106, penetrating through layers to form an electrical connection. However, due to the proximity the via 114 to the source/drain regions of the FETs 102/104, an insulating liner is used to prevent shorting between these structures.

Five different cross-sections are illustrated. A first cross-section, AA, cuts through the gate 112, perpendicular to the FETs 102/114, and includes the via 114. A second cross-section, BB, cuts parallel to the gates 112, perpendicular to the FETs 102/114, in a source/drain region. A third cross-section, CC, cuts through the signal/clock line 106, parallel to the FETs 102/104. A fourth cross-section, DD, cuts through one of the FETs 102/104, perpendicular to the gates 112. A fifth cross-section, A′A′, cuts through the same plane as AA, but includes a wider view of that plane.

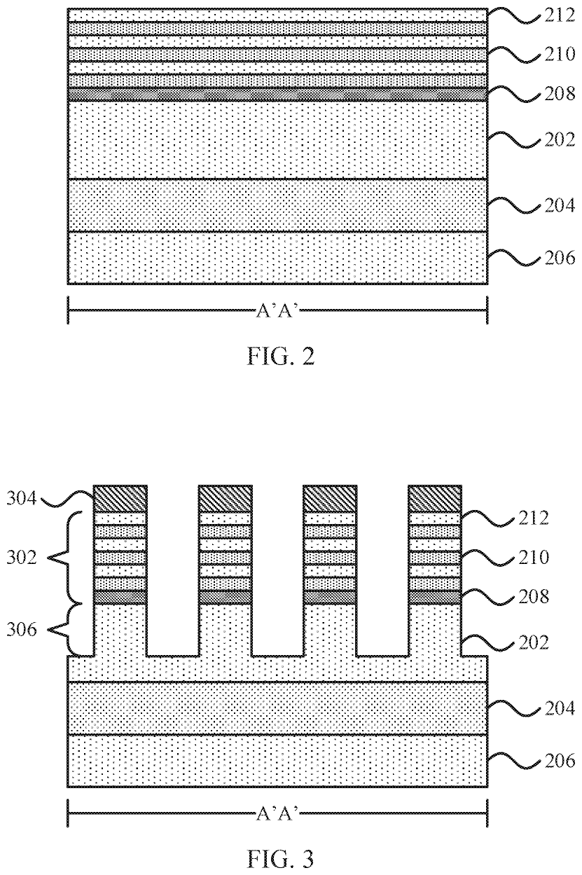

Referring now to FIG. 2, a cross-sectional view of a step in the fabrication of a semiconductor device is shown, along cross-section A′A′. A substrate is shown, including a device semiconductor layer 202, a buried insulator layer 204, and a bulk semiconductor layer 206. On top of the substrate, a series of semiconductor layers may be formed by successive epitaxial growth processes. The semiconductor layers may include, e.g., a first sacrificial semiconductor layer 208, second sacrificial semiconductor layers 210, and channel layers 212.

The device semiconductor layer 102 may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The buried insulator layer 104 may be, e.g., silicon dioxide or any other appropriate material. The bulk semiconductor layer 206 is contemplated as being formed from silicon, but it should be understood that any appropriate material may be used instead to provide structural support to the device being fabricated.

The series of semiconductor layers may include materials that are compatible with the material of the device semiconductor layer 202 for epitaxial growth, while being selectively etchable with respect to one another. For example, if the device semiconductor layer 202 is formed from silicon, then the first sacrificial semiconductor layer 208 may be formed from silicon germanium with a first germanium concentration, the second sacrificial semiconductor layers 210 may be formed from silicon germanium with a second germanium concentration, and the channel layers 212 may be formed from silicon.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

As used herein, the term “selective” in reference to a material removal process denotes that the rate of material removal for a first material is greater than the rate of removal for at least another material of the structure to which the material removal process is being applied. In examples where silicon germanium is used in the first sacrificial layer 208 and the second sacrificial layers 210, the respective germanium concentrations may be selected to make the materials selectively etchable, such that the first sacrificial layer 208 may be removed without removing the second sacrificial layers 210 and channel layers 212, and such that the second sacrificial layers 210 may be removed without removing the channel layers 212. It is specifically contemplated that the first germanium concentration may be about 50%-70%, with a specific example being about 55%, and that the second germanium concentration may be about 20%-40%, with a specific example being about 30%.

Referring now to FIG. 3, a cross-sectional view of a step in the fabrication of a semiconductor device is shown, along cross-section A′A′. The semiconductor layers are masked and etched using any appropriate photolithographic process. For example, a layer of masking material may be deposited using any appropriate deposition process. The masking material may be patterned to produce masks 304 on the semiconductor layers. One or more selective anisotropic etches may then be used to remove the exposed portions of the semiconductor layers and may further cut down into the device semiconductor substrate 202 to form plateaus 306.

In a photolithographic process, a pattern may be produced by applying a photoresist material to the surface to be etched. The photoresist is exposed to a pattern of radiation and is the pattern is developed into the photoresist utilizing a resist developer. Once the patterning of the photoresist to form the mask 304, the sections covered by the photoresist are protected while the exposed regions are removed using a selective etching process that removes the unprotected regions.

Reactive Ion Etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation. The etch process is selected to selectively remove material from the channel layers 212, the second semiconductor layers 210, the first semiconductor layer 208, and the device semiconductor substrate 202, without removing the mask 304.

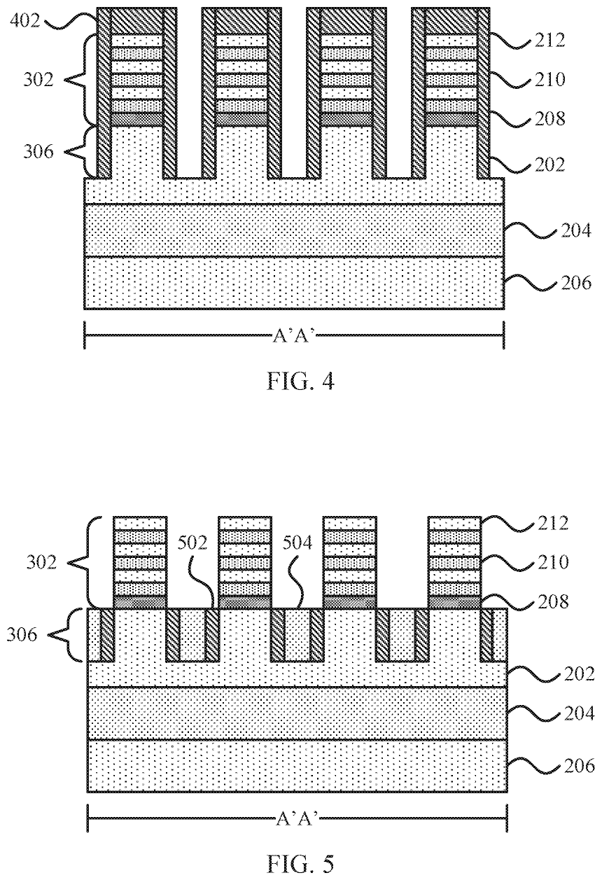

Referring now to FIG. 4, a cross-sectional view of a step in the fabrication of a semiconductor device is shown, along cross-section A′A′. A dielectric liner 402 is formed on sidewalls of the stacks 302 and the pillars 306. The liner 402 may be formed by depositing a dielectric material using any appropriate conformal deposition process. The dielectric material may then be removed from horizontal surfaces using a selective anisotropic etch, leaving the liner 402 on vertical sidewalls. In some examples, the liner 402 may be formed using atomic layer deposition (ALD) to deposit a layer of silicon dioxide, silicon nitride, silicon carbonitride, silicon oxycarbonitride, etc.

The dielectric material may alternatively be deposited by any appropriate process including, e.g., chemical vapor deposition (CVD) or physical vapor deposition (PVD). CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface.

Referring now to FIG. 5, a cross-sectional view of a step in the fabrication of a semiconductor device is shown, along cross-section A′A′. The space between the stacks 302 is filled with a dielectric material that is separately etchable with respect to the material of liner 402. For example, if the liner 402 is formed from silicon nitride, then the dielectric fill may be formed from silicon dioxide. Both the dielectric fill and the liner 402 are etched back to the height of the plateaus 306 using any appropriate isotropic or anisotropic etching process. The remaining dielectric liner 502 and dielectric fill 504 form two-component STI structures that separate adjacent devices from one another. At this stage, the mask 304 may be removed using any appropriate isotropic or anisotropic etching process.

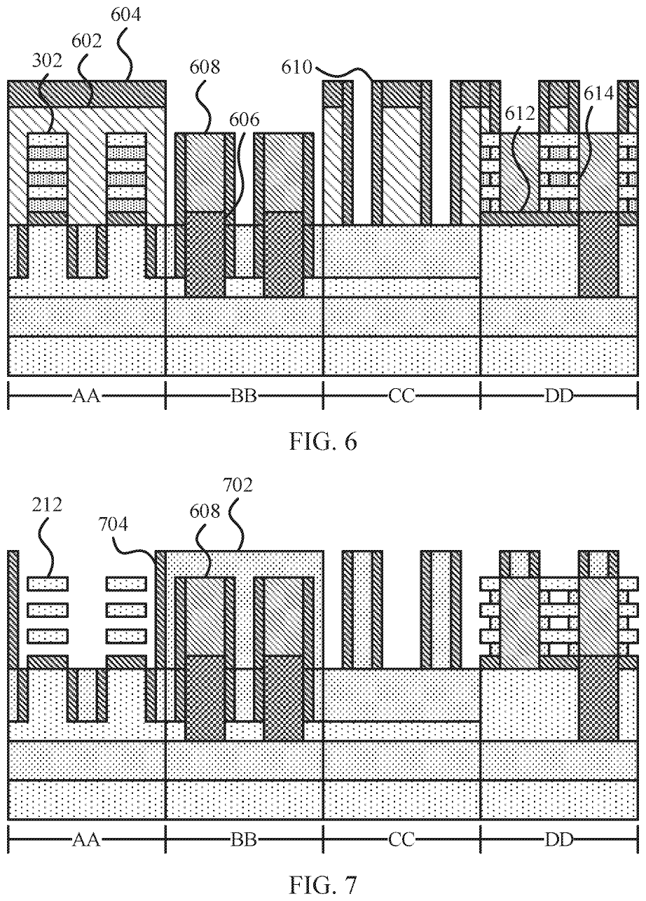

Referring now to FIG. 6, cross-sectional views of a step in the fabrication of a semiconductor device is shown, along cross-sections AA, BB, CC, and DD. In the interest of compactness, only the center two stacks 302 are shown in these cross-sectional views. A number of steps are performed to process the stacks 302.

A dummy gate 602 is formed across the stacks 302. This may include depositing a layer of dummy gate material, such as polysilicon, by any appropriate deposition process. The dummy gate material may then be patterned using a photolithographic mask 604 and a selective anisotropic etch process.

The first sacrificial semiconductor layer 208 may be selectively etched away using an isotropic etch that removes material from underneath the stacks 302. A bottom dielectric isolation layer 612 may be formed in the space left by the removal of the first sacrificial semiconductor layer 208, for example by conformally depositing a dielectric material such as silicon dioxide. Dielectric material may also be deposited on sidewalls of the stacks 302 and dummy gates 602 to form sidewall spacers from, e.g., silicon dioxide, silicon nitride, silicon oxynitride, silicon oxycarbonitride, or any other appropriate dielectric material. A selective anisotropic etch may be used to remove the dielectric material from horizontal surfaces.

In regions outside of the dummy gates 602, the portion of the device semiconductor substrate 102 underneath the stacks 302 may be etched away and replaced by a sacrificial placeholder 606. These sacrificial placeholders 606 may be formed from any dielectric material having appropriate etch selectivity with respect to surrounding dielectric materials, and may positioned in regions where source/drain structures will subsequently be formed, establishing locations where bottom source/drain contacts will later be formed. The stacks 302 in these areas, between and around the dummy gates 602, may be etched away and replaced by source/drain structures 608, for example by epitaxially growing doped semiconductor material from sidewalls of the channel layers 212. The etch may be selective to the semiconductor materials of the stacks 302, without harming the dummy gates 602 and the sidewall spacers 610.

Inner spacers 614 may be formed at sidewalls of the second sacrificial layers 210. In some embodiments, inner spacers 614 may be formed by an oxidation process that forms silicon dioxide from the silicon germanium of the second sacrificial layers 210 at a greater rate than is formed from the silicon of the channel layers 212. In some embodiments, the inner spacers 614 may be formed by selectively recessing the second sacrificial layers 210 and conformally depositing a dielectric material in the recesses. Dielectric material outside of the recesses may then be anisotropically etched away, leaving the inner spacers 614 protected within the recesses.

Referring now to FIG. 7, cross-sectional views of a step in the fabrication of a semiconductor device is shown, along cross-sections AA, BB, CC, and DD. An interlayer dielectric 702 is deposited around the dummy gates 602 by any appropriate deposition process, such as a flowable CVD of silicon dioxide. A gate cut 704 is formed, for example by removing the mask 604 and patterning the dummy gates 602 to remove dummy gate material in particular areas to separate device regions as appropriate. The gaps left by patterning the dummy gates 602 may be filled with dielectric material, such as silicon nitride, to form the gate cuts 704.

After formation of the gate cutes 704, the dummy gates 602 may be selectively etched away using any appropriate isotropic or anisotropic etching process, thereby exposing the stacks 302. Remaining portions of the second sacrificial layers 210 are selectively etched away, releasing the channel layers 212, which remains suspended by the source/drain structures 608.

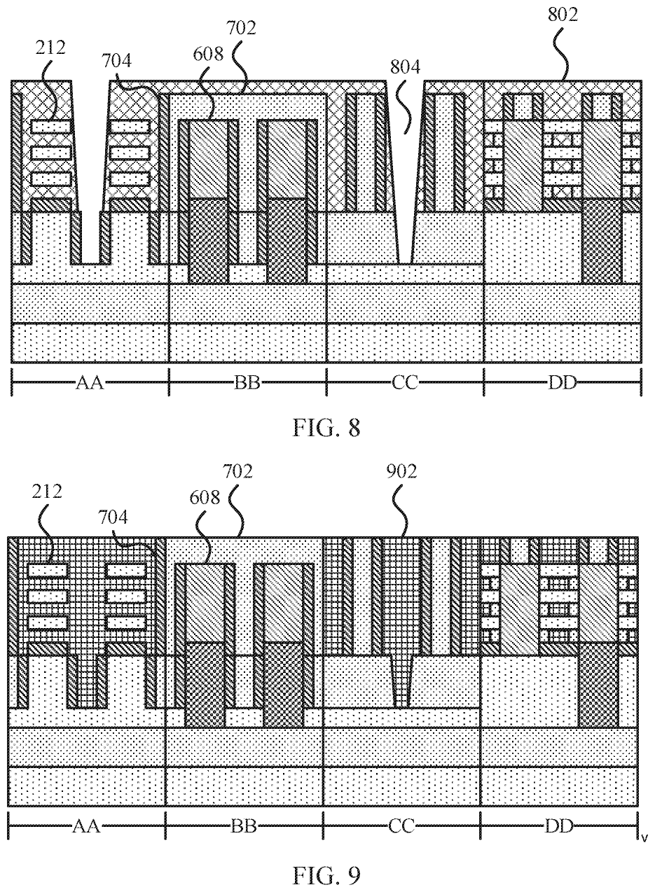

Referring now to FIG. 8, cross-sectional views of a step in the fabrication of a semiconductor device is shown, along cross-sections AA, BB, CC, and DD. An organic planarizing layer (OPL) 802 is deposited over the wafer using any appropriate deposition process, filling in the gaps between semiconductor channels 212. The OPL 802 is patterned to form openings 804 between device regions. Once the underlying STI region is exposed, then the exposed dielectric fill 504 may be selectively etched away, leaving the dielectric liner 502 in place.

Referring now to FIG. 9, cross-sectional views of a step in the fabrication of a semiconductor device is shown, along cross-sections AA, BB, CC, and DD. The OPL 802 may be removed, for example using an ashing process that leaves other structures intact. A gate stack may then be formed over and around the channel layers 212. The gate stack may include, for example, a gate dielectric layer (not shown), a work function metal layer (not shown), and a gate conductor 902. The gate conductor 902 may be formed by depositing conductive material using any appropriate conformal deposition process, to a height that exceeds the height of the interlayer dielectric 702. Excess conductive material may then be removed using a chemical mechanical planarization (CMP) process that stops on the material of the interlayer dielectric 702. Because of the formation of via 804 through the STI layer, the gate conductor 902 extends down to a level below the bottom of the top surface of the device semiconductor layer 102.

The gate dielectric layer may be formed from, e.g., a high-k dielectric, which may be any material having a dielectric constant greater than that of silicon dioxide. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The work function metal layer may be a p-type work function metal layer or an n-type work function metal layer, as appropriate to the device in question. As used herein, a “p-type work function metal layer” is a metal layer that effectuates a p-type threshold voltage shift. In one embodiment, the work function of the p-type work function metal layer ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In one embodiment, a p-type work function metal layer may be formed from titanium nitride, titanium aluminum nitride, ruthenium, platinum, molybdenum, cobalt, and alloys and combinations thereof.

As used herein, an “n-type work function metal layer” is a metal layer that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In one embodiment, the work function of the n-type work function metal layer ranges from 4.1 eV to 4.3 eV. In one embodiment, the n-type work function metal layer is formed from at least one of titanium aluminum, tantalum nitride, titanium nitride, hafnium nitride, hafnium silicon, or combinations thereof. It should be understood that titanium nitride may play the role of an n-type work function metal or a p-type work function metal, depending on the conditions of its deposition.

The gate conductor 902 may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductor 902 may alternatively be formed from a doped semiconductor material such as, e.g., doped polysilicon.

CMP is performed using, e.g., a chemical or granular slurry and mechanical force to gradually remove upper layers of the device. The slurry may be formulated to be unable to dissolve, for example, the work function metal layer material, resulting in the CMP process's inability to proceed any farther than that layer.

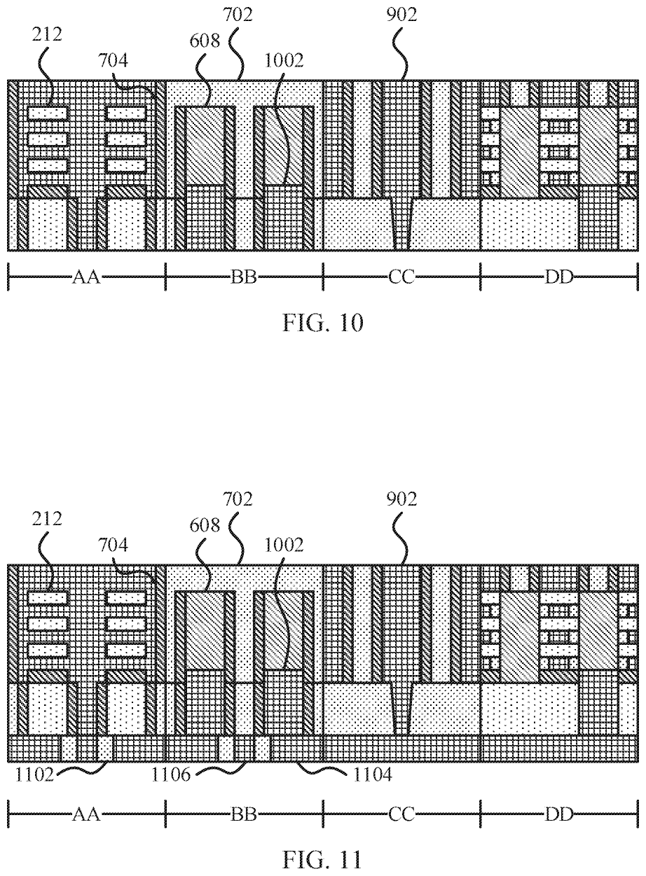

Referring now to FIG. 10, cross-sectional views of a step in the fabrication of a semiconductor device is shown, along cross-sections AA, BB, CC, and DD. The top surface of the wafer may be bonded to a handler wafer (not shown) so that the wafer may be turned upside down and so that the backside may be processed. The back layers are removed, including bulk semiconductor layer 206, buried insulator layer 204, and any parts of the device semiconductor layer 202 that remain below the bottom surface of the STI structures. For example, the lower part of the device semiconductor layer 202 may be removed using a CMP process that stops on, e.g., the dielectric material of one or both of the STI structures.

Removal of the lower part of the device semiconductor layer 202 may expose a bottom surface of the gate conductor 902, for example at the via that passes through the dielectric fill 504 of the STI structure. The sacrificial placeholders 606 are also exposed. The sacrificial placeholders 606 may be selectively etched away and replaced with conductive contacts 1002 that make electrical contact with the source/drain structures 608 from below. The conductive contacts 1002 may be formed from any appropriate conductive material and may have a dielectric liner (not shown) that prevents shorting between the conductive contacts 1002 and the device semiconductor layer 202.

Referring now to FIG. 11, cross-sectional views of a step in the fabrication of a semiconductor device is shown, along cross-sections AA, BB, CC, and DD. A backside power/signal layer is formed on the backside of the wafer. The backside power layer may include a dielectric layer 1102, such as silicon dioxide, and may be formed by any appropriate deposition process. Trenches may be formed in the dielectric layer 1102 and may be filled with conductive material to form power lines 1104 and clock/signal line 1106. The power lines 1104 may be formed in regions to make electrical contact with the conductive contacts 1002, and the clock/signal line 1106 may be positioned to make electrical contact with the bottom surface of the gate conductor 902.

Additional power and signal distribution layers may be formed on the frontside and backside of the chip, to distribute power and signals to the devices in the front-end-of-line (FEOL) layer. These layers may include frontside and backside back-end-of-line (BEOL) layers, for example including successive layers of dielectric material with respective conductive lines and vias that form a power distribution network and/or signal communication paths.

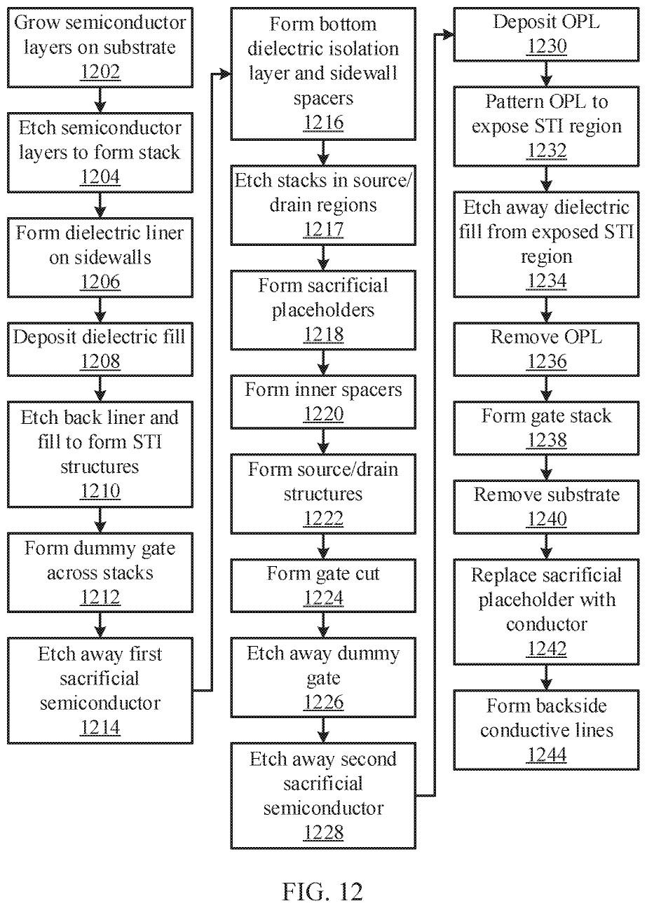

Referring now to FIG. 12, a method of forming a semiconductor device is shown. Block 1202 grows semiconductor layers on a substrate. For example, epitaxial growth processes may be used to form a first sacrificial semiconductor layer 208 on a device semiconductor layer 202, for example growing silicon germanium with a first germanium concentration on a silicon substrate. Alternating second semiconductor layers 210 and channel layers 212 may then be grown from the top surface of the first sacrificial semiconductor layer 208, for example including silicon germanium layers with a second germanium concentration and silicon layers.

Block 1204 etches the semiconductor layers to form stacks 302. Block 1204 may include the photolithographic patterning of a mask 304, followed by a selective anisotropic etch that removes material of the channel layers 212, the second sacrificial semiconductor layers 210, the first sacrificial semiconductor layer 208, and the device semiconductor layer 202, leaving trenches in the device semiconductor layer 202. Block 1206 forms a dielectric liner 402 on the sidewalls of the stacks 302 and the trenches, for example by conformally depositing a dielectric material such as silicon nitride and anisotropically etching the dielectric material from horizontal surfaces. Block 1208 deposits a dielectric fill material, such as silicon dioxide, to fill the trenches. Block 1210 then etches the dielectric fill and the liner 402 back, for example to the level of the top surface of the device semiconductor layer 202, to form STI liner 502 and STI fill 504.

Block 1212 forms dummy gates 610 across the stacks 302, for example by depositing polycrystalline silicon and patterning using a photolithographic mask 604. Block 1214 etches away the first sacrificial semiconductor layer 208 using a selective isotropic etch that removes the second semiconductor material from underneath the stacks 302. Block 1216 then conformally deposits dielectric material, such as silicon dioxide, that forms a bottom dielectric isolation layer in the space left by removing the first sacrificial semiconductor layer 208 and that forms sidewall spacers 610 on the dummy gates 602, for example using silicon nitride.

Block 1217 selectively etches away the stacks 302 in source/drain regions, for example using a selective anisotropic etch to remove material that is not covered by the dummy gates 602. Block 1218 forms sacrificial placeholders 606 in any regions where a bottom source/drain contact will later be formed, for example by anisotropically etching through the device semiconductor layer 202 to expose the buried insulator layer 204, depositing the placeholder material, and etching any excess placeholder material back to an appropriate height.

Block 1220 forms inner spacers 614 on the stacks 302, for example using an oxidation process that preferentially forms silicon dioxide at side surfaces of the second sacrificial semiconductor layers 210 or by recessing the second sacrificial semiconductor layers 210 and conformally depositing dielectric material in the recesses. Block 1222 then forms source/drain structures by epitaxially growing doped semiconductor material from exposed side surfaces of the channel layers 212.

Block 1224 forms a gate cut 704. This may be performed by, e.g., depositing an interlayer dielectric 702 around the dummy gates 602 and patterning and etching the dummy gates 602 to form holes that reach down to the STI structures. Dielectric material may be formed in the holes to form gate cut structures 704, which may be used in subsequent steps to separate a gate structure into separate device regions.

Block 1226 then etches away the dummy gates 602, for example using a selective isotropic or anisotropic etch. Block 1228 etches away the second sacrificial semiconductor layers 210, exposing the top and bottom surfaces of the channel layers 212, using a selective isotropic etch.

Block 1230 deposits OPL 802 using any appropriate deposition process and block 1232 patterns the OPL to form hole 804, exposing a portion of the top surface of an STI structure. Block 1234 then etches away the exposed dielectric fill 504 of the STI structure to expose a portion of the device semiconductor layer 202 under the STI region. Block 1236 removes the OPL 802, for example using an ashing process.

Block 1238 forms a gate stack on the exposed channel layers 212, for example by depositing a gate dielectric layer (not shown), a work function metal layer (not shown), and a gate conductor 902. The gate conductor fills the opening in the STI region to make contact with the underlying device semiconductor layer 202.

Block 1240 removes the substrate, including the bulk semiconductor layer 206, the buried insulator layer 204, and lower parts of the device semiconductor layer 202. This step may include bonding the wafer to a handler wafer (not shown) and turning the wafer upside-down before any appropriate etching or polishing process is used to remove the bottom layers. Block 1242 replaces the sacrificial placeholder structure(s) with 606 with a conductive material to form source/drain contacts 1002. Block 1244 then forms backside conductive lines, for example including power lines 1104 and signal/clock lines 1106 in a backside dielectric layer 1102.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including.” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for case of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of self-aligned backside contacts (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a channel over a backside layer;
a dielectric fill on the backside layer, including a first dielectric material;
a gate conductor on the channel that makes electrical contact with the backside layer through the dielectric fill; and
a dielectric liner on sidewalls of the dielectric fill, including a second dielectric material, in contact with the gate conductor at the dielectric fill.

2. The semiconductor device of claim 1, wherein the dielectric liner covers opposing sidewalls of a hole in the dielectric fill.

3. The semiconductor device of claim 1, further comprising:
a source/drain structure in electrical contact with the channel; and
a bottom source/drain contact that makes electrical contact between the source/drain structure and a power line in the backside layer.

4. The semiconductor device of claim 3, wherein the dielectric fill and the dielectric liner are part a shallow trench isolation (STI) structure that runs parallel to an orientation of the channel and the source/drain structure.

5. The semiconductor device of claim 1, wherein the gate conductor makes electrical contact with a signal line in the backside layer.

6. The semiconductor device of claim 1, further comprising:
a semiconductor structure between the channel and the backside layer; and
a bottom dielectric isolation layer between the semiconductor structure and the channel.

7. The semiconductor device of claim 6, wherein the dielectric liner is formed on a sidewall of the semiconductor structure.

8. The semiconductor device of claim 1, wherein the first dielectric material is silicon dioxide and the second dielectric material is silicon nitride.

9. A semiconductor device, comprising:
a first channel over a backside layer in a first device region;
a second channel over the backside layer in a second device region;
a dielectric fill that includes a first dielectric layer, on the backside layer between the first device region and the second device region;
a gate conductor on the first channel and the second channel that makes electrical contact with the backside layer through the dielectric fill; and
a dielectric liner on sidewalls of the dielectric fill, including a second dielectric material, in contact with the gate conductor at the dielectric fill.

10. The semiconductor device of claim 9, wherein the dielectric liner covers opposing sidewalls of a hole in the dielectric fill.

11. The semiconductor device of claim 9, further comprising:
a source/drain structure in electrical contact with the channel; and
a bottom source/drain contact that makes electrical contact between the source/drain structure and a power line in the backside layer.

12. The semiconductor device of claim 11, wherein the dielectric fill and the dielectric liner are part a shallow trench isolation (STI) structure that runs parallel to an orientation of the channel and the source/drain structure.

13. The semiconductor device of claim 9, wherein the gate conductor makes electrical contact with a signal line in the backside layer.

14. The semiconductor device of claim 9, further comprising:
a semiconductor structure between the channel and the backside layer; and
a bottom dielectric isolation layer between the semiconductor structure and the channel.

15. The semiconductor device of claim 14, wherein the dielectric liner is formed on a sidewall of the semiconductor structure.

16. A method for forming a semiconductor device, comprising:
etching a set of vertically stacked semiconductor layers and an underlying substrate to form a trench;
forming a multilayer dielectric structure at a bottom of the trench, including a liner on sidewalls of the trench from a first dielectric material and a fill from a second dielectric material;
processing the set of vertically stacked semiconductor layers to form a channel layer;
etching a hole through the fill to expose a portion of the underlying substrate; and
depositing a gate conductor that makes electrical contact with the channel layer and that fills the hole.

17. The method of claim 16, further comprising forming a signal line on a backside surface to make electrical contact with the gate conductor at the hole.

18. The method of claim 16, further comprising:
forming a placeholder structure that penetrates the underlying substrate; and
forming a source/drain structure on the channel layer, over the placeholder structure.

19. The method of claim 18, further comprising:
etching away the placeholder structure from a backside surface to form a gap under the source/drain structure;
forming a conductive contact in the gap in electrical contact with the source/drain structure; and
forming a power line on the backside surface to make electrical contact with the conductive contact.

20. The method of claim 16, wherein forming the multilayer dielectric structure includes:
conformally depositing the first dielectric material on sidewalls of the trench;
anisotropically etching the first dielectric material from horizontal surfaces;
depositing the second dielectric material to fill the trench;
etching back the first and second dielectric material to a height of a top surface of the underlying substrate.
